(19) United States
(12) Patent Application Publication
(10) Pub. No.: US 2023/0282254 A1
(43) Pub. Date: Sep. 7, 2023

(54) METHOD FOR DYNAMICALLY RESIZING INSTRUCTION MEMORY AND DATA MEMORY IN SYSTEM AND ASSOCIATED SYSTEM

(71) Applicant: Realtek Semiconductor Corp., HsinChu (TW)

(72) Inventors: Wei-Shu Huang, HsinChu (TW); Hsieh-Han Chiang, HsinChu (TW)

(73) Assignee: Realtek Semiconductor Corp., HsinChu (TW)

(21) Appl. No.: 17/976,891

(22) Filed: Oct. 31, 2022

(30) Foreign Application Priority Data
Mar. 4, 2022 (TW) 111107993

(51) Int. Cl. G11C 7/10

(52) U.S. Cl. CPC G11C 7/1096; G11C 7/1045; G11C 7/1063

(57) ABSTRACT

A method for dynamically resizing an instruction memory and a data memory in a system includes: defining, by a memory control circuit, a plurality of memory selection modes; selecting a memory selection mode from the plurality of memory selection modes, and writing the memory selection mode into a firmware control register; and redistributing, by the memory control circuit, a plurality of memory cells in the instruction memory and a plurality of memory cells in the data memory according to the memory selection mode stored in the firmware control register.

### BACKGROUND OF THE INVENTION

### 1. Field of the Invention

The present invention is related to memory control, and more particularly, to a method for dynamically resizing an instruction memory and a data memory in a system, and an associated system thereof.

### 2. Description of the Prior Art

In different products or applications that include a system on a chip (SoC), requirements for a size ratio between an instruction memory and a data memory (e.g. both are included in a static random access memory (SRAM)) may be different. When there are limitations to the cost and size of an SRAM size, e.g. for embedded use in an application, there will be a trade off in the size ratio between the instruction memory and the data memory. The typical distribution of the instruction memory and the data memory, however, is fixed before a tape-out stage, which may cause a lack of flexibility in embedded use.

As a result, a method for dynamically resizing an instruction memory and a data memory in a system, and an associated system thereof, are urgently needed, to improve performance of a control processing unit (CPU) in a chip and increase the flexibility in embedded use.

### SUMMARY OF THE INVENTION

It is therefore an objective of the present invention to provide a method for dynamically resizing an instruction memory and a data memory in a system, and an associated system thereof, to address the above-mentioned problems.

According to an embodiment of the present invention, a method for dynamically resizing an instruction memory and a data memory in a system is provided. The method may include: defining, by a memory control circuit, a plurality of memory selection modes; selecting a memory selection mode from the plurality of memory selection modes, and writing the memory selection mode into a firmware control register; and redistributing, by the memory control circuit, a plurality of memory cells in the instruction memory and a plurality of memory cells in the data memory according to the memory selection mode stored in the firmware control register.

According to an embodiment of the present invention, a system for dynamically resizing an instruction memory and a data memory is provided. The system may include a memory control circuit and a firmware control circuit. The memory control circuit may be arranged to define a plurality of memory selection modes, and redistribute a plurality of memory cells in the instruction memory and a plurality of memory cells in the data memory according to a memory selection mode stored in the firmware control register. The firmware control register may be arranged to store the memory selection mode selected from the plurality of memory selection modes.

One of the benefits of the present invention is that a system (e.g. an embedded system) provided by the present invention can utilize hardware-software co-design (e.g. the firmware control register and the SRAM control circuit in the system) to distribute a part of memory cells in one of the instruction memory and the data memory to another of the instruction memory and the data memory (i.e. dynamically resize the instruction memory and the data memory). In this way, during boot startup of the system, the firmware control register can select a memory selection mode with more data memory from a plurality of memory selection modes to store the data section and the stack into the data memory, to improve performance of the CPU (e.g. the embedded system can have a higher DMIPS score). In addition, during firmware operation of the system, the firmware control register can select different memory selection modes from the plurality of memory selection modes according to different designed firmware functions, to dynamically resize the data section and the text section, which can increase the flexibility in embedded use.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a system for dynamically resizing an instruction memory and a data memory according to an embodiment of the present invention.

FIG. 2 is a diagram illustrating switching between memory selection modes defined by an SRAM control circuit shown in FIG. 1 according to an embodiment of the present invention.

FIG. 3 is a flow chart of utilizing the system shown in FIG. 1 to dynamically resize the instruction memory and the data memory according to an embodiment of the present invention.

FIG. 4 is an example of selecting different memory selection modes from a plurality of memory selection modes according to different applications corresponding to the system shown in FIG. 1 according to an embodiment of the present invention.

FIG. 5 is an example of utilizing the SRAM control circuit shown in FIG. 1 to switch the memory selection modes according to an embodiment of the present invention.

FIG. 6 is a flow chart of a method for dynamically resizing the instruction memory and the data memory in the system according to an embodiment of the present invention.

### DETAILED DESCRIPTION

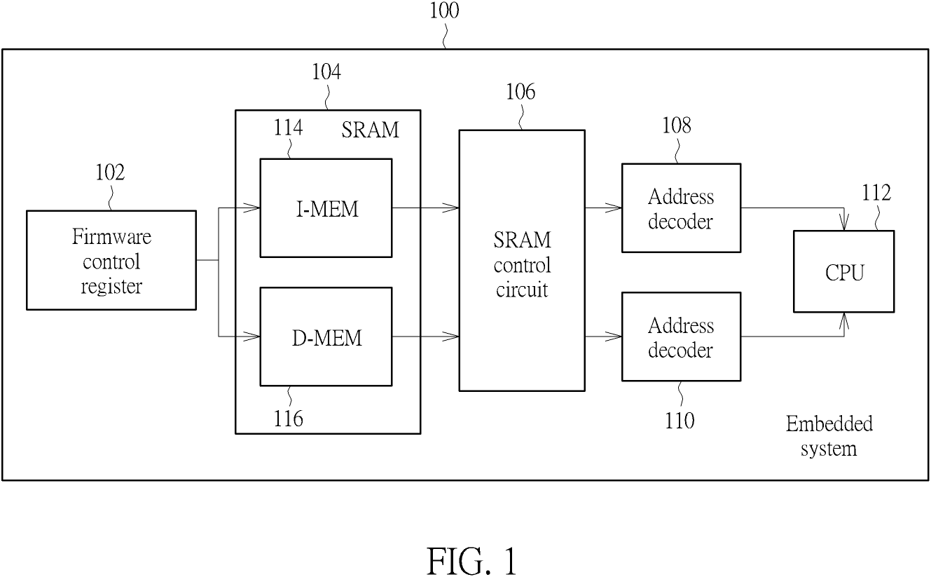

FIG. 1 is a diagram illustrating a system for dynamically resizing an instruction memory (for brevity, referred to as “I-MEM”) and a data memory (for brevity, referred to as “D-MEM”) according to an embodiment of the present invention. The system (e.g. an embedded system 100) may include a firmware control register 102, a memory (e.g. a static random access memory (SRAM) 104), a memory control circuit (e.g. an SRAM control circuit 106), a plurality of address decoders 108 and 110, and a central processing unit (CPU) 112, wherein a size of the SRAM 104 is fixed, and the SRAM 104 may include an I-MEM 114 and a D-MEM 116. Under a condition that the size of the SRAM 104 is fixed, in order to dynamically resize the I-MEM 114 and the D-MEM 116, the SRAM control circuit 106 may first define a plurality of memory selection modes, and then redistribute a plurality of memory cells in the I-MEM 114 and a plurality of memory cells in the D-MEM 116 by switching the plurality of memory selection modes (i.e. dynamically resize the I-MEM 114 and the D-MEM 116). The address decoders 108 and 110 may maintain continuity of addresses of the plurality of memory cells in the I-MEM 114 and continuity of addresses of the plurality of memory cells in the D-MEM 116, respectively.

The firmware control register 102 may be arranged to store a memory selection mode selected from the plurality of memory selection modes, and dynamically resize data section and text section according to different conditions of the embedded system 100. For example, during boot startup of the embedded system 100, the firmware control register 102 can select a memory selection mode with more D-MEM 116 from the plurality of memory selection modes to store the data section and stack into the D-MEM 116, which improves performance of the CPU 112 (e.g. the embedded system 100 may have a higher Dhrystone million instructions executed per second (DMIPS) score). In another example, during firmware operation of the embedded system 100, the firmware control register 102 can select different memory selection modes from the plurality of memory selection modes according to different designed firmware functions, to dynamically resize the data section and the text section.

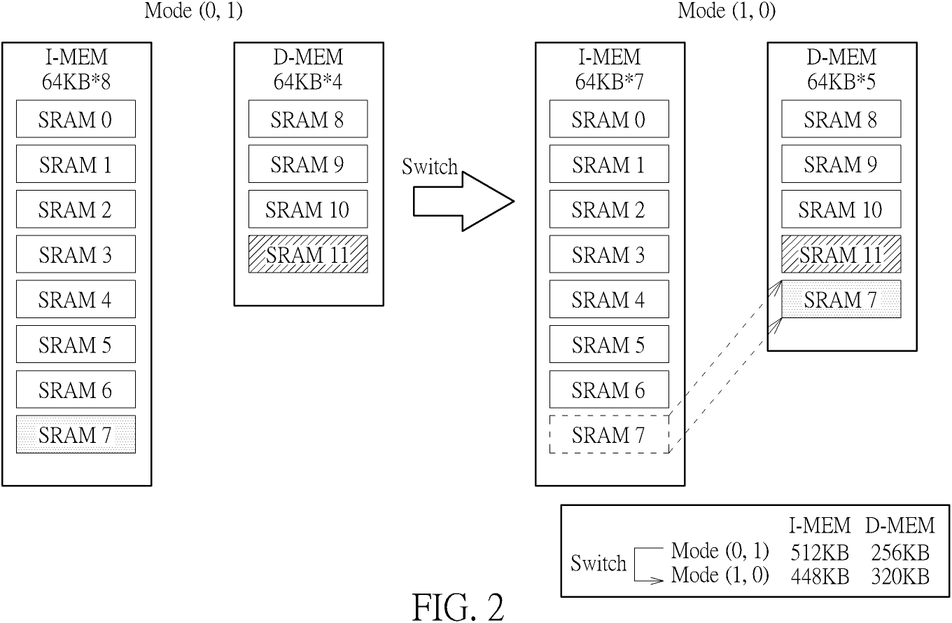

FIG. 2 is a diagram illustrating switching between the memory selection modes defined by the SRAM control circuit 106 shown in FIG. 1 according to an embodiment of the present invention. In this embodiment, the size of the SRAM 104 is fixed at 768 kilobytes (KB), and the SRAM control circuit 106 defines 2 memory selection modes (e.g. mode (0, 1) and mode (1, 0)). In the mode (0, 1), the I-MEM 114 may include 8 groups of memory cells with 64 KB (labeled as “SRAMO, SRAM1, ..., and SRAM7”, respectively; i.e. a size of the I-MEM 114 is 512 KB (64 KB*8)), and the D-MEM 116 may include 4 groups of memory cells with 64 KB (labeled as “SRAM8, SRAM9, SRAM10, and SRAM11”, respectively; i.e. a size of the D-MEM 116 is 256 KB (64KB*4) ) . In the mode (1, 0), the I-MEM 114 may include 7 groups of memory cells with 64 KB (labeled as “SRAM0, SRAM1, ..., and SRAM6”, respectively; i.e. the size of the I-MEM 114 is 448 KB (64 KB*7)), and the D-MEM 116 may include 5 groups of memory cells with 64 KB (labeled as “SRAM8, SRAM9, SRAM10, SRAM11, and SRAM7”, respectively; i.e. the size of the D-MEM 116 is 320 KB (64 KB*5)). This is for illustrative purposes only, and the present invention is not limited thereto. The number of the memory selection modes depends on actual design considerations.

In this embodiment, the SRAM control circuit 106 may switch the mode (0, 1) to the mode (1, 0) to dynamically resize the I-MEM 114 and the D-MEM 116, wherein the group of memory cells with 64 KB that are labeled as “SRAM7” in the I-MEM 114 may be redistributed into the D-MEM 116, so that the size of the I-MEM 114 may be decreased and the size of the D-MEM 116 may be increased. After the I-MEM 114 and the D-MEM 116 have already been dynamically resized, the address decoder 110 may be arranged to redistribute an address of the group of memory cells with 64 KB that are labeled as “SRAM7” in the D-MEM 116, to maintain the continuity of addresses of 5 groups of memory cells (i.e. 5 groups of memory cells with 64 KB that are labeled as “SRAM8, SRAM9, SRAM10, SRAM11, and SRAM7”, respectively) in the D-MEM 116.

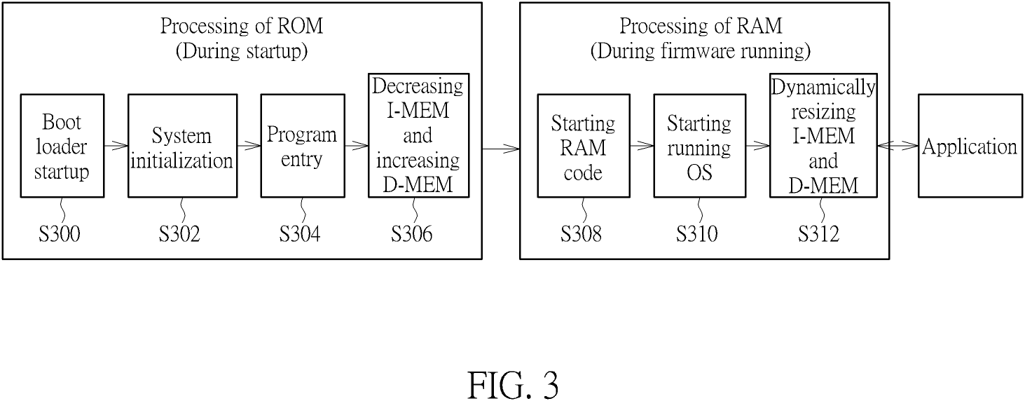

FIG. 3 is a flow chart of utilizing the system (e.g. the embedded system 100) shown in FIG. 1 to dynamically resize the I-MEM 114 and the D-MEM 116 according to an embodiment of the present invention. As shown in FIG. 3, after the embedded system 100 is powered on, processing of a read-only memory (ROM) may include boot loader startup (Step S300), system initialization (Step S302), and program entry (Step 304). Before processing of a random access memory (RAM) is entered, during the processing of the ROM, the firmware control register 102 may select a memory selection mode with more D-MEM 116 from the plurality of memory selection modes to store the data section and the stack into the D-MEM 116, to improve the performance of the CPU 112. In this way, during the startup of the embedded system 100, the size of the I-MEM 114 may be decreased and the size of the D-MEM 116 may be increased by the firmware control register 102 and the SRAM control circuit 106 (Step S306; for brevity, labeled as “Decreasing I-MEM and increasing D-MEM” in FIG. 3).

The processing of the RAM may include starting a RAM code (Step S308) and starting running an operating system (OS) (Step S310). After the OS starts running, the firmware register 102 may select different memory selection modes from the plurality of memory selection modes according to different applications corresponding to the embedded system 100. That is, when a firmware of the embedded system 100 runs, a memory selection mode may be selected from the plurality of memory selection modes according to an application of the embedded system 100, and the I-MEM 114 and the D-MEM 116 may be resized dynamically according to the memory selection mode (Step S312; for brevity, labeled as “Dynamically resizing I-MEM and D-MEM” in FIG. 3). For example, the size of the I-MEM 114 may be decreased and the size of the D-MEM 116 may be increased, or the size of the I-MEM 114 may be increased and the size of the D-MEM 116 may be decreased.

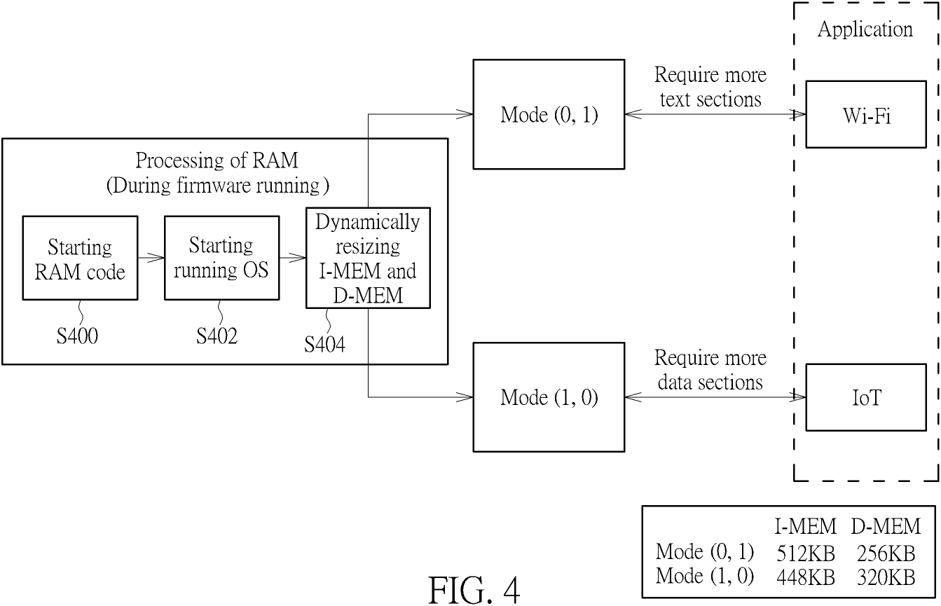

FIG. 4 is an example of selecting different memory selection modes from the plurality of memory selection modes according to different applications corresponding to the system shown in FIG. 1 according to an embodiment of the present invention. As shown in FIG. 4, the processing of the RAM may include starting the RAM code (Step S400), starting running the OS (Step S402), and dynamically resizing the I-MEM 114 and the D-MEM 116 (Step S404), wherein Steps S400, S402, and S404 may be implemented by Steps S308, S310, and S312 shown in FIG. 3; for brevity, further descriptions are not repeated in detail here. In this embodiment, the applications corresponding to the embedded system 100 may include wireless fidelity (Wi-Fi; assuming that Wi-Fi requires more text sections) and Internet of Things (IoT; assuming that IoT requires more data sections, such as video image processing), but the present invention is not limited thereto. The plurality of memory selection modes defined by the SRAM control circuit 106 may include 2 memory selection modes (e.g. the modes (0, 1) and (1, 0) shown in FIG. 2). Compared with the mode (1, 0), in the mode (0, 1), the I-MEM 114 has more memory cells (i.e. the size of the I-MEM 114 in the mode (0, 1) is larger than that in the mode (1, 0)). Compared with the mode (0, 1), in the mode (1, 0), the D-MEM 116 has more memory cells (i.e. the size of the D-MEM 116 in the mode (1, 0) is larger than that in the mode (0, 1)). As a result, in response to the Wi-Fi application requiring more text sections, the mode (0, 1) may be written into the firmware control register 102 to increase the size of the text section. In response to the IoT application requiring more data sections, the mode (1, 0) may be written into the firmware control register 102 to increase the size of the data section.

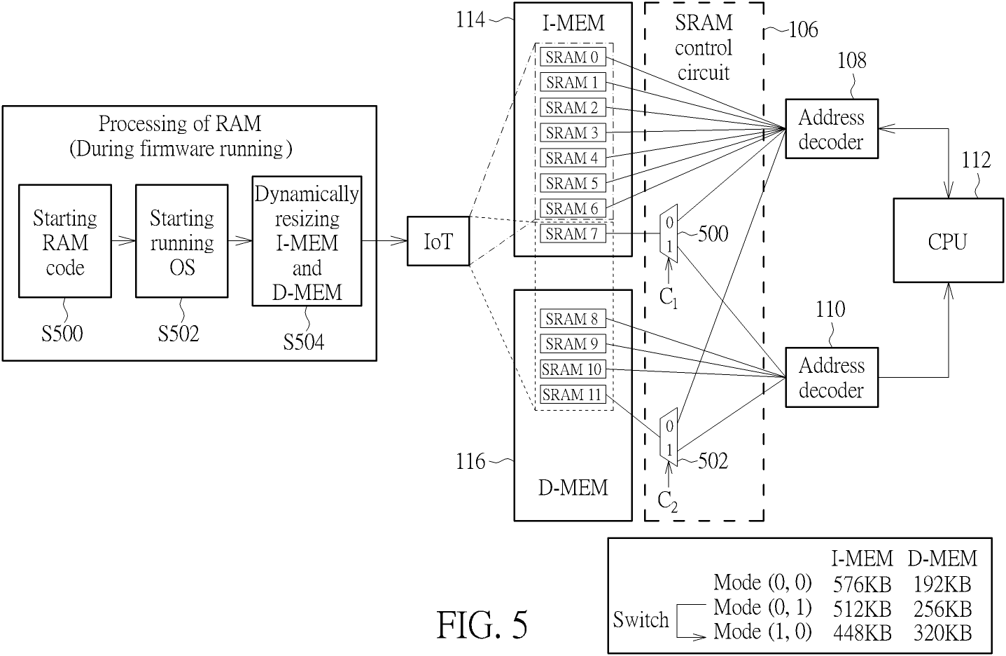

FIG. 5 is an example of utilizing the SRAM control circuit 106 shown in FIG. 1 to switch the memory selection modes according to an embodiment of the present invention. As shown in FIG. 5, the processing of the RAM may include starting the RAM code (Step S500), starting running the OS (Step S502), and dynamically resizing the I-MEM 114 and the D-MEM 116 (Step S504), wherein Steps S500, S502, and S504 may be implemented by Steps S308, S310, and S312 shown in FIG. 3; for brevity, further descriptions are not repeated in detail here. In this embodiment, it is assumed that the application corresponding to the embedded system 100 is IoT (assuming that IoT requires more data sections; for example, video image processing), the plurality of memory selection modes defined by the SRAM control circuit 106 may include 3 memory selection modes (e.g. the modes (0, 1) and (1, 0) shown in FIG. 2 and a mode (0, 0)), and the current memory selection mode is the mode (0, 1), wherein in the mode (0, 0), the I-MEM 114 may include 9 groups of memory cells with 64 KB (i.e. the size of the I-MEM 114 is 576 KB (64 KB*9)), and the D-MEM 116 may include 3 groups of memory cells with 64 KB (i.e. the size of the D-MEM 116 is 192 KB (64 KB*3)).

The SRAM control circuit 106 may include a plurality of demultiplexers 500 and 502. The demultiplexer 500 has a first input terminal, a first output terminal (labeled as “0” in FIG. 5), and a second output terminal (labeled as “1” in FIG. 5), wherein the first output terminal may be coupled to the address decoder 108, the second output terminal may be coupled to the address decoder 110, and the first input terminal may be arranged to receive the group of memory cells with 64 KB that are labeled as “SRAM7” in the I-MEM 114, and couple the first input terminal to one of the first output terminal and the second output terminal according to a first selection signal C₁, for redistributing the group of memory cells with 64 KB that are labeled as “SRAM7” in the I-MEM 114 to the I-MEM 114 or the D-MEM 116. The demultiplexer 502 has a second input terminal, a third output terminal (labeled as “0” in FIG. 5), and a fourth output terminal (labeled as “1” in FIG. 5), wherein the third output terminal may be coupled to the address decoder 108, the fourth output terminal may be coupled to the address decoder 110, and the second input terminal may be arranged to receive the group of memory cells with 64 KB that are labeled as “SRAM11” in the D-MEM 116, and couple the second input terminal to one of the third output terminal and the fourth output terminal according to a second selection signal C₂, for redistributing the group of memory cells with 64 KB that are labeled as “SRAM11” in the D-MEM 116 to the I-MEM 114 or the D-MEM 116.

Since the IoT application requires more data sections and the current memory selection mode is the mode (0, 1), the SRAM control circuit 106 may switch the memory selection mode from the mode (0, 1) to the mode (1, 0) by the demultiplexers 500 and 502, to decrease the size of the I-MEM 114 and increase the size of the D-MEM 116. In the process of switching, the demultiplexer 500 may couple the first input terminal to the second output terminal (i.e. the address decoder 110) according to the first selection signal C₁, to distribute the group of memory cells with 64 KB that are labeled as “SRAM7” in the I-MEM 114 to the D-MEM 116. The demultiplexer 502 may couple the second input terminal to the fourth output terminal (i.e. the address decoder 110) according to the second selection signal C₂, to distribute the group of memory cells with 64 KB that are labeled as “SRAM11” in the D-MEM 116 to the D-MEM 116.

It should be noted that, in this embodiment, a group of memory cells with 64 KB in one of the I-MEM 114 and the D-MEM 116 may be distributed to another of the I-MEM 114 and the D-MEM 116 by switching the memory selection mode, but the present invention is not limited thereto. Any system that utilizes hardware-software co-design (e.g. the firmware control register 102 and the SRAM control circuit 106) to distribute a part of memory cells in one of the I-MEM 114 and the D-MEM 116 to another of the I-MEM 114 and the D-MEM 116 (i.e. to dynamically resize the I-MEM 114 and the D-MEM 116) will fall within the scope of the present invention.

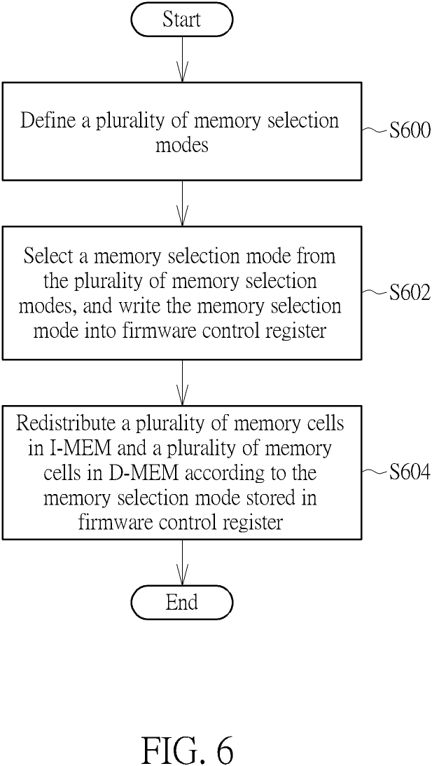

FIG. 6 is a flow chart of a method for dynamically resizing the instruction memory and the data memory in the system according to an embodiment of the present invention. Provided that the result is substantially the same, the steps are not required to be executed in the exact order shown in FIG. 6. For example, the method for dynamically resizing the instruction memory and the data memory in the system shown in FIG. 6 may be employed by the firmware control register 102 and the SRAM control circuit 106 shown in FIG. 1.

In Step S600, a plurality of memory selection modes are defined by the SRAM control circuit 106.

In Step S602, a memory selection mode is selected from the plurality of memory selection modes, and the memory selection mode is written into the firmware control register 102.

In Step 604, a plurality of memory cells in the I-MEM 114 and a plurality of memory cells in the D-MEM 116 are redistributed according to the memory selection mode stored in the firmware control register 102.

Since a person skilled in the pertinent art can readily understand details of the steps shown in FIG. 6 after reading the above paragraphs, further description is omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for dynamically resizing an instruction memory and a data memory in a system, comprising:
defining, by a memory control circuit, a plurality of memory selection modes;
selecting a memory selection mode from the plurality of memory selection modes, and writing the memory selection mode into a firmware control register; and
redistributing, by the memory control circuit, a plurality of memory cells in the instruction memory and a plurality of memory cells in the data memory according to the memory selection mode stored in the firmware control register.

2. The method of claim 1, wherein in response to the system being powered on, the instruction memory and the data memory are dynamically resized during process of a read-only memory of the system.

3. The method of claim 2, wherein a size of the data memory is increased and a size of the instruction memory is decreased.

4. The method of claim 1, wherein in response to a firmware of the system running, the instruction memory and the data memory are dynamically resized during process of a random access memory of the system.

5. The method of claim 1, wherein selecting the memory selection mode from the plurality of memory selection modes comprises:
according to an application of the system, selecting the memory selection mode from the plurality of memory selection modes.

6. The method of claim 5, wherein a size of the instruction memory is increased and a size of the data memory is decreased.

7. The method of claim 5, wherein a size of the instruction memory is decreased and a size of the data memory is increased.

8. The method of claim 1, wherein redistributing, by the memory control circuit, the plurality of memory cells in the instruction memory and the plurality of memory cells in the data memory according to the memory selection mode stored in the firmware control register comprises:
distributing a part of memory cells of one of the instruction memory and the data memory to another of the instruction memory and the data memory.

9. The method of claim 1, further comprising:
maintaining, by a plurality of address decoders, continuity of addresses of the plurality of memory cells in the instruction memory and continuity of addresses of the plurality of memory cells in the data memory.

10. A system for dynamically resizing an instruction memory and a data memory, comprising:
a memory control circuit, arranged to define a plurality of memory selection modes, and redistribute a plurality of memory cells in the instruction memory and a plurality of memory cells in the data memory according to a memory selection mode stored in a firmware control register; and
the firmware control register, arranged to store the memory selection mode selected from the plurality of memory selection modes.
